(19) United States
(12) Patent Application Publication
(10) Pub. No.: US 2024/0243075 A1
(43) Pub. Date: Jul. 18, 2024

(54) CHIP PACKAGE WITH HEAT DISSIPATION AND ELECTROMAGNETIC PROTECTION

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/393,633

(22) Filed: Dec. 21, 2023

(30) Foreign Application Priority Data
Jan. 17, 2023 (TW) 112101997

(51) Int. Cl. H01L 23/552; H01L 21/56; H01L 23/373

(52) U.S. Cl. CPC H01L 23/552; H01L 21/561; H01L 23/3736; H01L 21/304

(57) ABSTRACT

A chip package with heat dissipation and electromagnetic protection is provided. The chip package includes a package unit and a heat dissipation shielding layer. A top portion of the package unit is formed by grinding of an original top of the package unit using grinding technique and a level of a back surface of at least one die is at the same level with the top portion of the package unit after the grinding. The heat dissipation shielding layer is completely covering the top portion of the package unit for providing functions of heat dissipation and electromagnetic protection to the package unit.

### CROSS-REFERENCE TO RELATED APPLICATIONS

This non-provisional application claims priority under 35 U.S.C. § 119(a) on patent application Ser. No. 11/210,1997 filed in Taiwan, R.O.C. on Jan. 17, 2023, the entire contents of which are hereby incorporated by reference.

### BACKGROUND OF THE INVENTION

The present invention relates to a chip package, especially to a chip package with heat dissipation and electromagnetic protection.

Chip packages generate heat during operation, especially high-power chips or power management chips are quite easier to get very hot. Good heat dissipation makes the chip work well. Poor heat dissipation cause performance issues and even results in chip failure. Thus removal of massive heat generated by the chip to keep the chip at normal operating temperature is necessary.

In the semiconductor field, there are already certain techniques available now which improve heat dissipation properties of chip packages such as those revealed in U.S. Pat. No. 8,193,622B2, Taiwanese Pat. No. 464833B, Chinese Pat. No. 101796637B, and Korean Pat. No. 101539250B1. Among these prior arts (including U.S. Pat. No. 8,193,622B2), upper and lower metal interlayers are used to provide good thermal conductivity and the exposed metal interlayers also dissipate heat. However, most the above prior arts improve heat dissipation efficiency by increasing number of heat sinks. Yet there is no effective solution to problems related to materials and thickness of the chip package itself which are unable to provide good heat dissipation. Moreover, the increasing of the heat sinks doesn't match the trend of compact and light-weight design of the chip package now. The design of the chip package also has requirements for avoiding external electromagnetic interference (EMI) or light interference. Thus efficacy and values of the chip package are further improved once the structural design for heat dissipation of the chip package also provides electromagnetic interference (EMI) protection.

### SUMMARY OF THE INVENTION

Therefore, it is a primary object of the present invention to provide a chip package with heat dissipation and electromagnetic protection. The chip package includes a package unit and a heat dissipation shielding layer. A top portion of the package unit is formed by grinding of an original top of the package unit using grinding technique and a level of a back surface of at least one die is at the same level with the top portion of the package unit after the grinding. The top portion of the package unit is completely covered with the heat dissipation shielding layer which provides functions of heat dissipation and electromagnetic protection to the package unit.

In order to achieve the above object, a chip package with heat dissipation and electromagnetic protection according to the present invention is provided. The chip package with heat dissipation and electromagnetic protection includes a package unit and a heat dissipation shielding layer. The package unit consists of a substrate, at least one first circuit layer, at least one second circuit layer, at least one die, and an insulating layer. The substrate is provided with a first surface and a second surface opposite to the first surface. The first circuit layer is disposed on the first surface of the substrate and provided with a first surface while the second circuit layer is arranged at the second surface of the substrate and electrically connected with the first circuit layer.

The die is mounted on the first surface of the first circuit layer by flip chip and composed of a front surface and a back surface opposite to the front surface. The front surface is electrically connected with the first circuit layer correspondingly. The insulating layer is disposed on the substrate and covering the die while the back surface of the die is exposed. A top portion of the package unit is formed by grinding an original top of the package unit with grinding technique. After the grinding, a level of the back surface of the die is the same with a level of the top portion of the package unit. The heat dissipation shielding layer is completely covering the top portion of the package unit for specifically providing functions of electromagnetic protection and heat dissipation to the package unit. A method of manufacturing the chip package includes the following steps. Step S1: providing a support board with a plurality of package units each of which includes a substrate, at least one first circuit layer, at least one second circuit layer, at least one die, and an insulating layer. The substrate consists of a first surface and a second surface opposite to each other. The first circuit layer is disposed on the first surface of the substrate and provided with a first surface while the second circuit layer is arranged at the second surface of the substrate and electrically connected with the first circuit layer. The die is mounted on the first surface of the first circuit layer by flip chip and provided with a front surface electrically connected with the first circuit layer. The insulating layer is disposed on the substrate and covering the die while a top of the insulating layer forms an original top of the package unit. Step S2: using grinding technique to grind the original top of the package unit until a back surface of the die is exposed and forming a top portion of the package unit at a level lower than the original top after the grinding. A level of the back surface of the die is the same with the level of the top portion of the package unit. Step S3: covering the top portion of the package unit with a heat dissipation shielding layer completely. Step S4: dividing the respective chip packages from the support board to get individual chip packages.

Preferably, the die further includes an original back surface. The back surface of the die is formed by the grinding in the step S2 of the original back surface so that the level of the back surface of the die is lower than a level of the original back surface of the die.

Preferably, after formation of the back surface of the die by the grinding in the step S2, a thickness of the die is equal or close to 20 micrometer (μm).

Preferably, a thickness of the package unit is 0.4 mm-1.0 mm. After the grinding, the thickness of the package unit is further reduced to 0.15 mm-0.3 mm.

Preferably, the heat dissipation shielding layer is formed by copper electroplating, nickel gold electroplating, silver adhesive coating, graphene coating, or direct adhesion of a heat sink.

### BRIEF DESCRIPTION OF THE DRAWINGS

FIG. 1 is a side view of a section of an embodiment according to the present invention;

FIG. 2 is a side view of a section of an embodiment in which a plurality of package units is located on a support board according to the present invention;

FIG. 3 is a partial enlarged view showing a package unit of the embodiment in FIG. 2 according to the present invention;

FIG. 4 is a side view of a section of an embodiment showing grinding of a package unit until an original back surface of a die exposed according to the present invention;

FIG. 5 is a schematic drawing of the embodiment in FIG. 4 showing grinding of an original back surface of a die until a back surface of the die exposed according to the present invention;

FIG. 6 is a side view of a section of an embodiment showing grinding of a package unit until a back surface of a die exposed according to the present invention;

FIG. 7 is a side view of a section of an embodiment showing a plurality of chip packages located on a support board according to the present invention.

### DETAILED DESCRIPTION OF THE PREFFERED EMBODIMENT

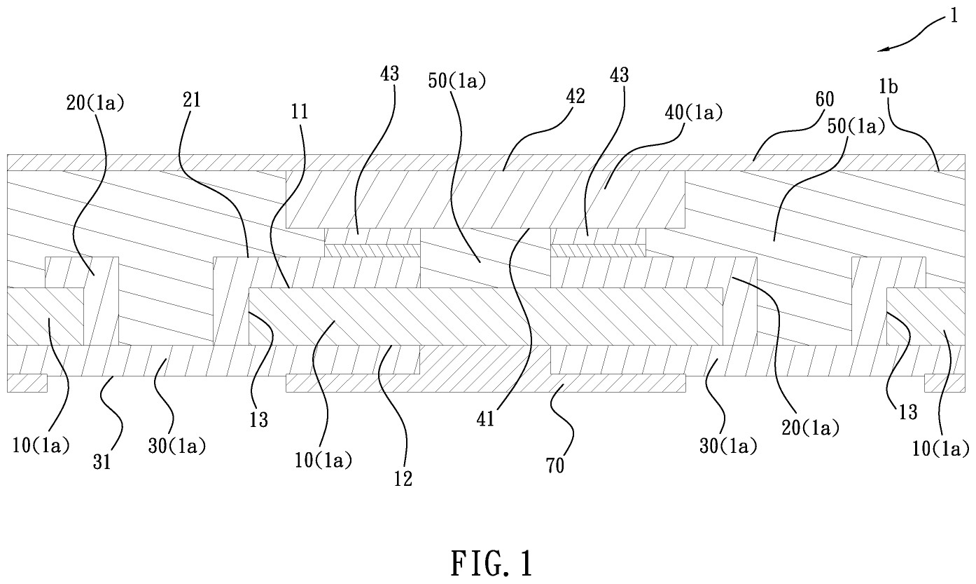

Refer to FIG. 1, a chip package 1 with heat dissipation and electromagnetic protection according to the present invention is provided. The chip package 1 includes a package unit 1a and a heat dissipation shielding layer 60.

Refer to FIG. 1, the package unit 1a consists of a substrate 10, at least one first circuit layer 20, at least one second circuit layer 30, at least one die 40, and an insulating layer 50. The substrate 10 is provided with a first surface 11 and a second surface 12 opposite to the first surface 11. The first circuit layer 20 is disposed on the first surface 11 of the substrate 10 and provided with a first surface 21 while the second circuit layer 30 is arranged at the second surface 12 of the substrate 10 and electrically connected with the first circuit layer 20. The die 40 is disposed on the first surface 21 of the first circuit layer 20 by flip chip and composed of a front surface 41 electrically connected with the first circuit layer 20 correspondingly and a back surface 42 opposite to the front surface 41. The insulating layer 50 is disposed on the substrate 10 and covering the die 40 while the back surface 42 of the die 40 is exposed. A top portion 1b of the package unit 1a is formed by grinding an original top 1c of the package unit 1a with grinding technique. After the grinding, a level of the back surface 42 of the die 40 is the same with a level of the top portion 1b of the package unit 1a.

A thickness of the package unit 1a is 0.4 mm-1.0 mm. After the grinding, the thickness of the package unit 1a is further reduced to 0.15 mm-0.3 mm, but not limited. This is beneficial to the thickness reduction of the chip products so that the chip products become thinner.

The heat dissipation shielding layer 60 is completely covering the top portion 1b of the package unit 1a for providing functions of electromagnetic protection and heat dissipation to the package unit 1a specifically.

The heat dissipation shielding layer 60 is formed by copper electroplating, nickel gold electroplating, silver adhesive coating, graphene coating, or direct adhesion of a heat sink. Thereby manufacturers can select heat-dissipating materials and dispose the heat-dissipating materials in different ways according to their needs.

A method of manufacturing the chip package 1 includes the following steps.

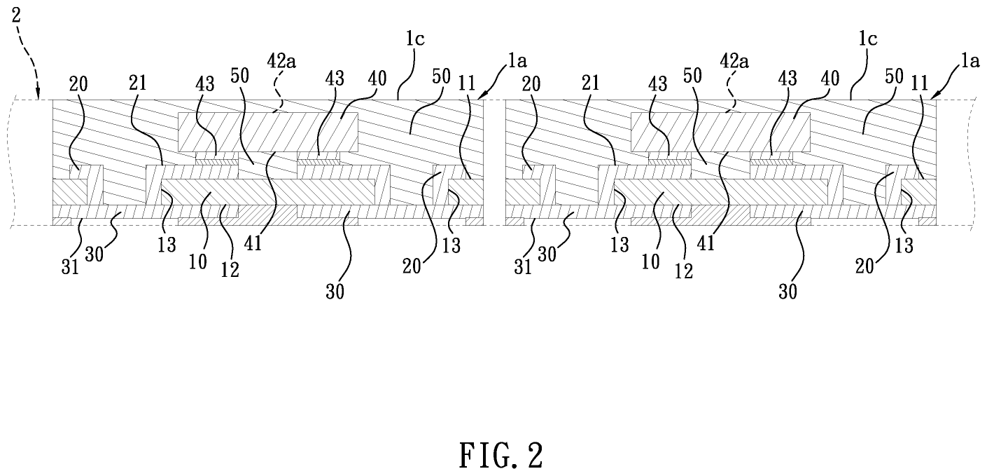

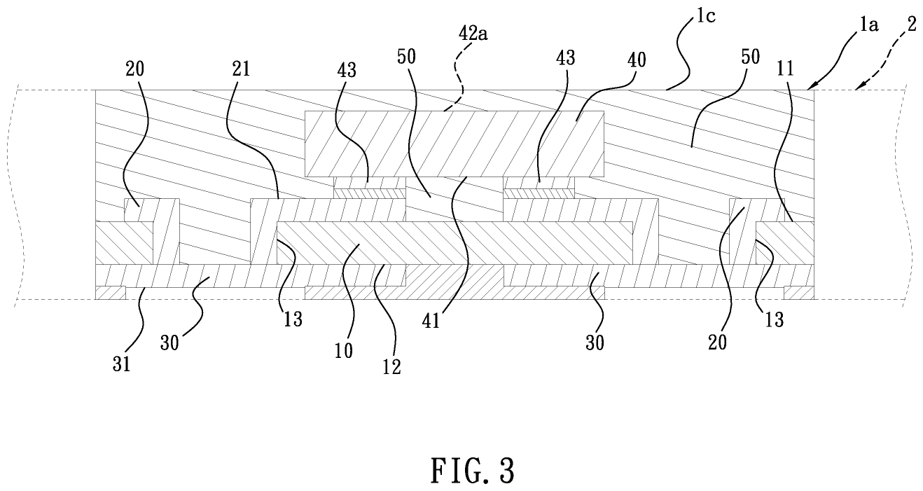

Step S1: providing a support board 2 with a plurality of package units 1a, as shown in FIG. 2, and each of the package units 1a includes a substrate 10, at least one first circuit layer 20, at least one second circuit layer 30, at least one die 40, and an insulating layer 50, as shown in FIG. 3. The substrate 10 consists of a first surface 11 and a second surface 12 opposite to the first surface 11. The first circuit layer 20 is disposed on the first surface 11 of the substrate 10 and provided with a first surface 21 while the second circuit layer 30 is arranged at the second surface 12 of the substrate 10 and electrically connected with the first circuit layer 20. The die 40 is disposed on the first surface 21 of the first circuit layer 20 by flip chip and provided with a front surface 41 electrically connected with the first circuit layer 20 correspondingly. The insulating layer 50 is mounted on the substrate 10 and covering the die 40 while a top of the insulating layer 50 forms an original top 1c of the package unit 1a, as shown in FIG. 3.

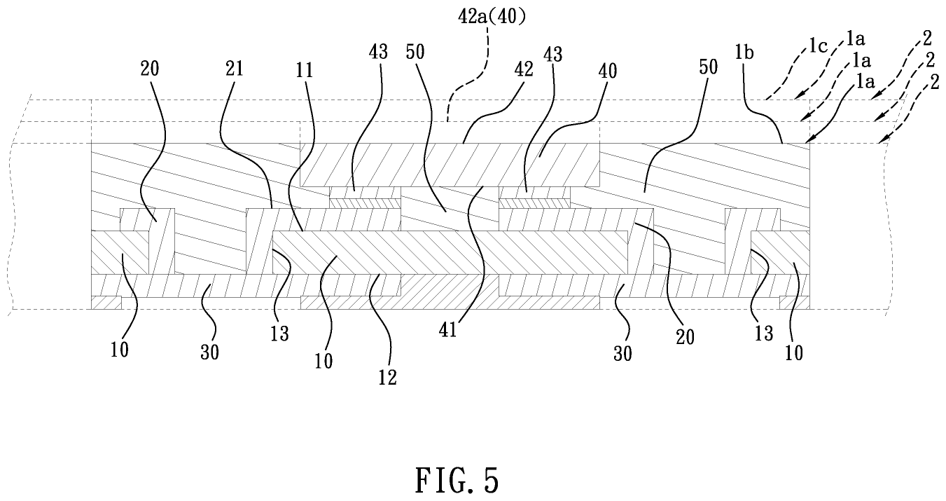

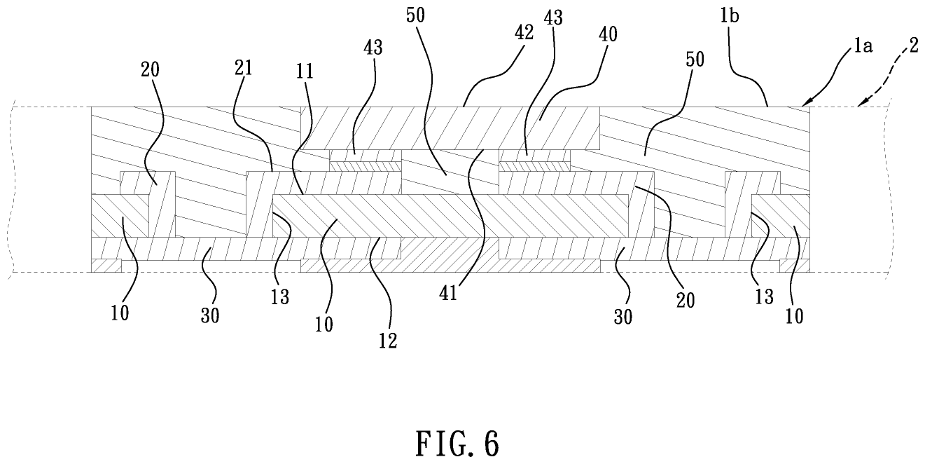

Step S2: using grinding technique to grind the original top 1c of the package unit 1a until a back surface 42 of the die 40 is exposed and forming a top portion 1b of the package unit 1a at a level lower than the original top 1c after the grinding, as shown in FIG. 5. A level of the back surface 42 of the die 40 is maintained at the same level of the top portion 1b of the package unit 1a, as shown in FIG. 6.

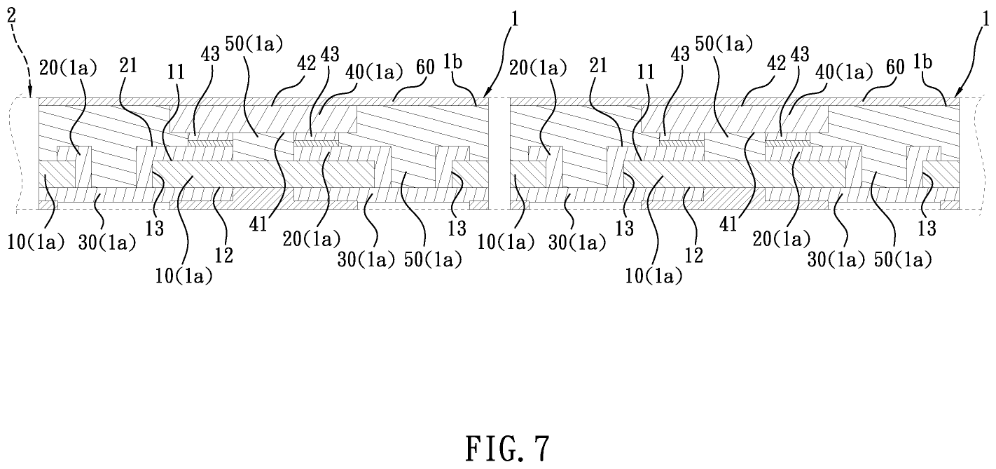

Step S3: covering the top portion 1b of the package unit 1a with a heat dissipation shielding layer 60 completely, as shown in FIG. 7.

Step S4: dividing the respective chip packages 1a from the support board 2 (as shown in FIG. 7) to get individual chip packages 1.

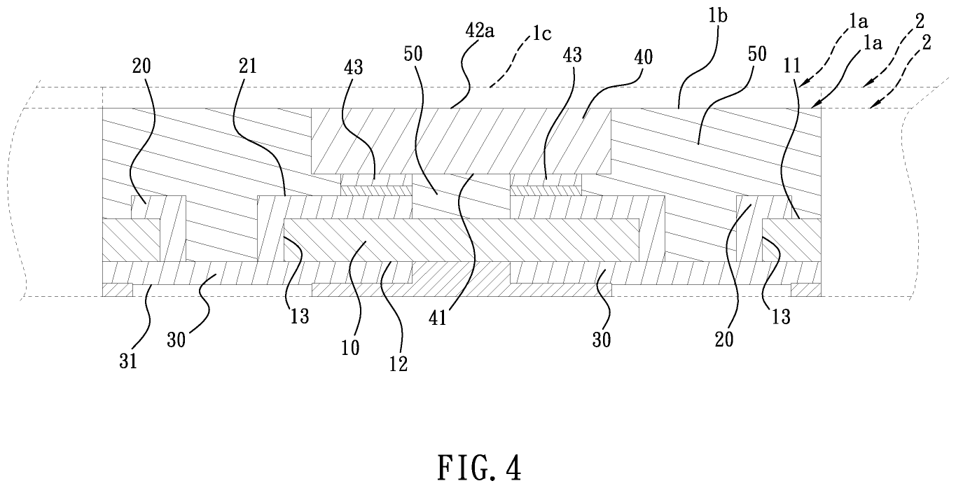

Refer to FIG. 4 and FIG. 5, in the step S2, first grinding the original top 1c of the package unit 1a until an original back surface 42a of the die 40 is exposed by the grinding technique, as shown in FIG. 4. Then grinding the original back surface 42a of the die 40 by the grinding technique again until the back surface 42 of the die 40 is exposed. Thereby the level of the back surface 42 of the die 40 is lower than a level of the original back surface 42a of the die 40, as shown in FIG. 5. This helps reduction of total thickness of the die 40.

After formation of the back surface 42 of the die 40 by the grinding in the step S2, a thickness of the die 40 is equal or close to 20 micrometer (μm), but not limited.

Refer to FIG. 1, the first surface 11 of the substrate 10 is further provided with at least one blind hole 13. The first circuit layer 20 is arranged at the first surface 11 of the substrate 10 and further extending to a surface of an inner wall of the blind hole 13 of the substrate 10. Thereby the first circuit layer 20 is electrically connected with the second circuit layer 30 due to extension of the first circuit layer 20 on the blind hole 13 of the substrate 10.

Refer to FIG. 1, the front surface 41 of the die 40 is provided with at least two separate die pads 43 which are electrically connected with the respective first circuit layers 20 correspondingly.

Refer to FIG. 1, the second circuit layer 30 further includes a first surface 31 which is further provided with an outer protective layer 70 for enhancement of structural strength of the chip package 1.

Compared with chip packages available now, the chip package 1 of the present invention has the following advantages.
(1) The top portion 1b of the package unit 1a is formed by grinding of the original top 1c of the package unit 1a using the grinding technique and the level of the back surface 42 of the die 40 is at the same level with the top portion 1b of the package unit 1a. Thereby the total thickness of the chip package 1 can be reduced and there is no need to treat the chip package 1 with commonly-used chemical mechanical polishing (CMP) now for reduction of thickness. There is no need to grind wafers to a thinner degree which makes manufacturing process harder.
(2) The heat dissipation shielding layer 60 is completely covering the top portion 1b of the package unit 1a for providing functions of heat dissipation and electromagnetic protection to the package unit 1a. A direct covering on the back surface 42 of the die 40 gives the shortest heat dissipation path. Thereby the problem of insufficient heat dissipation of the chip package available now can be solved and electromagnetic protection of the chip package is enhanced.

1. A chip package with heat dissipation and electromagnetic protection comprising:
a package unit which includes a substrate, at least one first circuit layer, at least one second circuit layer, at least one die, and an insulating layer; wherein the substrate is provided with a first surface and a second surface opposite to the first surface; wherein the first circuit layer is disposed on the first surface of the substrate and provided with a first surface; wherein the second circuit layer is arranged at the second surface of the substrate and electrically connected with the first circuit layer; wherein the die is mounted on the first surface of the first circuit layer by flip chip and composed of a front surface electrically connected with the first circuit layer correspondingly and a back surface opposite to the front surface; wherein the insulating layer is disposed on the substrate and covering the die while the back surface of the die is exposed; wherein a top portion of the package unit is formed by grinding an original top of the package unit with grinding technique and a level of the back surface of the die is the same with a level of the top portion of the package unit after the grinding; and
a heat dissipation shielding layer which is completely covering the top portion of the package unit for providing functions of electromagnetic protection and heat dissipation to the package unit specifically;
wherein a method of manufacturing the chip package includes the following steps:
Step S1: providing a support board with a plurality of package units each of which includes a substrate, at least one first circuit layer, at least one second circuit layer, at least one die, and an insulating layer; wherein the substrate consists of a first surface and a second surface opposite to each other; wherein the first circuit layer is disposed on the first surface of the substrate and provided with a first surface; wherein the second circuit layer is arranged at the second surface of the substrate and electrically connected with the first circuit layer; wherein the die is mounted on the first surface of the first circuit layer by flip chip and provided with a front surface electrically connected with the first circuit layer; wherein the insulating layer is disposed on the substrate and covering the die while a top of the insulating layer forms an original top of the package unit;
Step S2: using grinding technique to grind the original top of the package unit until a back surface of the die is exposed and forming a top portion of the package unit at a level lower than the original top after the grinding;
wherein a level of the back surface of the die is the same with the level of the top portion of the package unit;
Step S3: covering the top portion of the package unit with a heat dissipation shielding layer completely; and
Step S4: dividing the respective chip packages from the support board to get individual chip packages.

2. The chip package as claimed in claim 1, wherein the die further includes an original back surface; wherein the back surface of the die is formed by the grinding in the step S2 of the original back surface so that the level of the back surface of the die is lower than a level of the original back surface.

3. The chip package as claimed in claim 2, wherein a thickness of the die is equal or close to 20 micrometer (μm) after formation of the back surface of the die by the grinding in the step S2.

4. The chip package as claimed in claim 1, wherein a thickness of the package unit is 0.4 mm-1.0 mm and the thickness of the package unit is further reduced to 0.15 mm-0.3 mm after the grinding.

5. The chip package as claimed in claim 1, wherein the heat dissipation shielding layer is formed by copper electroplating or nickel gold electroplating.

6. The chip package as claimed in claim 1, wherein the heat dissipation shielding layer is formed by silver adhesive coating or graphene coating.

7. The chip package as claimed in claim 1, wherein the heat dissipation shielding layer is formed by direct adhesion of a heat sink.

8. The chip package as claimed in claim 1, wherein the first surface of the substrate is further provided with at least one blind hole and the first circuit layer disposed on the first surface of the substrate is extending to a surface of an inner wall of the blind hole of the substrate; thereby the first circuit layer is electrically connected with the second circuit layer due to extension of the first circuit layer on the blind hole of the substrate.
